(19) United States
(12) Patent Application Publication
(10) Pub. No.: US 2026/0040646 A1
(43) Pub. Date: Feb. 5, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Shu-Uei JANG, Hsinchu (TW); Shih-Yao LIN, New Taipei City (TW)

(21) Appl. No.: 18/793,765

(22) Filed: Aug. 3, 2024

(51) Int. Cl. H01L 29/66; H01L 29/06; H01L 29/423; H01L 29/775; H01L 29/786

(52) U.S. Cl. CPC H10D 64/018; H10D 30/6735; H10D 64/021; H10D 64/516; H10D 30/43; H10D 30/6757; H10D 62/121

(57) ABSTRACT

Embodiments of the present disclosure provide semiconductor device structures and methods of forming the same. The structure includes a semiconductor layer disposed over a substrate, and the semiconductor layer has a first length and a first width. The structure further includes a first inner spacer disposed on the semiconductor layer, and the first inner spacer has a second length substantially less than the first length and a second width substantially greater than the first width. The structure further includes a gate structure disposed adjacent the first inner spacer, and the gate structure surrounds at least a portion of the semiconductor layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of one of various stages of manufacturing a semiconductor device structure, in accordance with some embodiments.

FIGS. 2A-2H are cross-sectional side views of various stages of manufacturing the semiconductor device structure taken along line A-A of FIG. 1, in accordance with some embodiments.

FIGS. 3A-3C are various views of one of various stages of manufacturing the semiconductor device structure, in accordance with some embodiments.

FIGS. 4A-4C are various views of one of various stages of manufacturing the semiconductor device structure, in accordance with some embodiments.

FIGS. 5A and 5B are cross-sectional top views of various stages of manufacturing the semiconductor device structure taken along line B-B of FIG. 4C, in accordance with some embodiments.

FIG. 6 is a perspective view of a portion of the semiconductor device structure of FIG. 5B, in accordance with some embodiments.

FIGS. 7A and 7B are cross-sectional top views of various stages of manufacturing the semiconductor device structure taken along line B-B of FIG. 4C, in accordance with some embodiments.

FIG. 8 is a perspective view of a portion of the semiconductor device structure of FIG. 7B, in accordance with some embodiments.

FIGS. 9A and 9B are cross-sectional side views of one of various stages of manufacturing the semiconductor device structure, in accordance with some embodiments.

FIGS. 10A and 10B are cross-sectional side views of one of various stages of manufacturing the semiconductor device structure, in accordance with some embodiments.

FIGS. 11A and 11B are cross-sectional top views of one of various stages of manufacturing the semiconductor device structure taken along line B-B of FIG. 4C, in accordance with some embodiments.

FIGS. 12A and 12B are cross-sectional side views of one of various stages of manufacturing the semiconductor device structure, in accordance with some embodiments.

FIGS. 13A and 13B are cross-sectional side views of one of various stages of manufacturing the semiconductor device structure, in accordance with some embodiments.

FIG. 14 is a perspective view of one of the various stages of manufacturing the semiconductor device structure, in accordance with some embodiments.

FIGS. 15A-15D are cross-sectional top views of various stages of manufacturing the semiconductor device structure taken along line C-C of FIG. 14, in accordance with some embodiments.

FIGS. 16A-16D are cross-sectional top views of various stages of manufacturing the semiconductor device structure taken along line C-C of FIG. 14, in accordance with alternative embodiments.

FIG. 17 is a perspective view of one of the various stages of manufacturing the semiconductor device structure, in accordance with some embodiments.

FIG. 18 is a cross-sectional top view of one of various stages of manufacturing the semiconductor device structure taken along line D-D of FIG. 17, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as forksheet FETs, gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

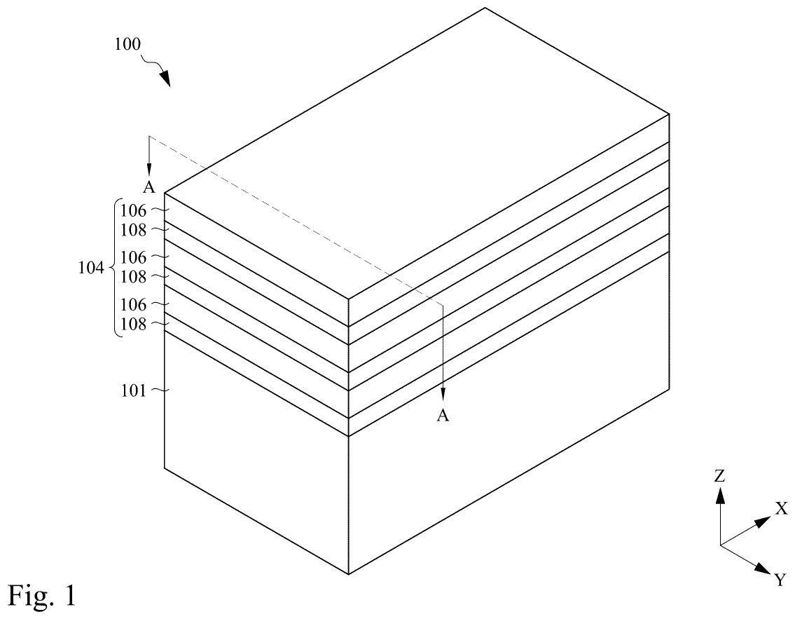

FIGS. 1-18 show exemplary processes for manufacturing a semiconductor device structure 100 according to embodiments of the present disclosure. It is understood that additional operations can be provided before, during, and after processes shown by FIGS. 1-18, and some of the operations described below can be replaced or eliminated, for additional embodiments of the method. The order of the operations/processes is not limiting and may be interchangeable.

FIG. 1 is a perspective view of one of various stages of manufacturing a semiconductor device structure 100, in accordance with some embodiments. As shown in FIG. 1, a semiconductor device structure 100 includes a stack of semiconductor layers 104 formed over a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as forksheet FETs, which is a type of nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor or a forksheet transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

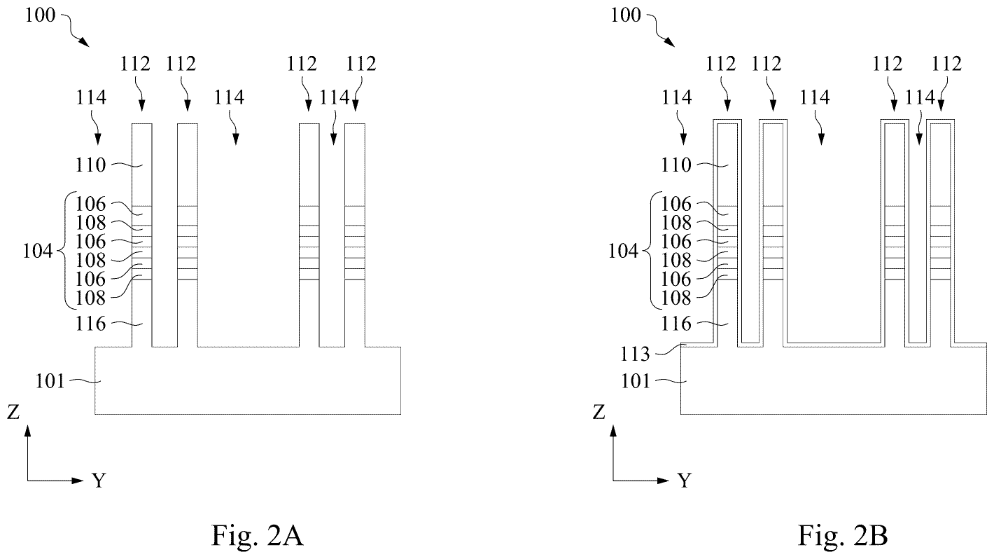

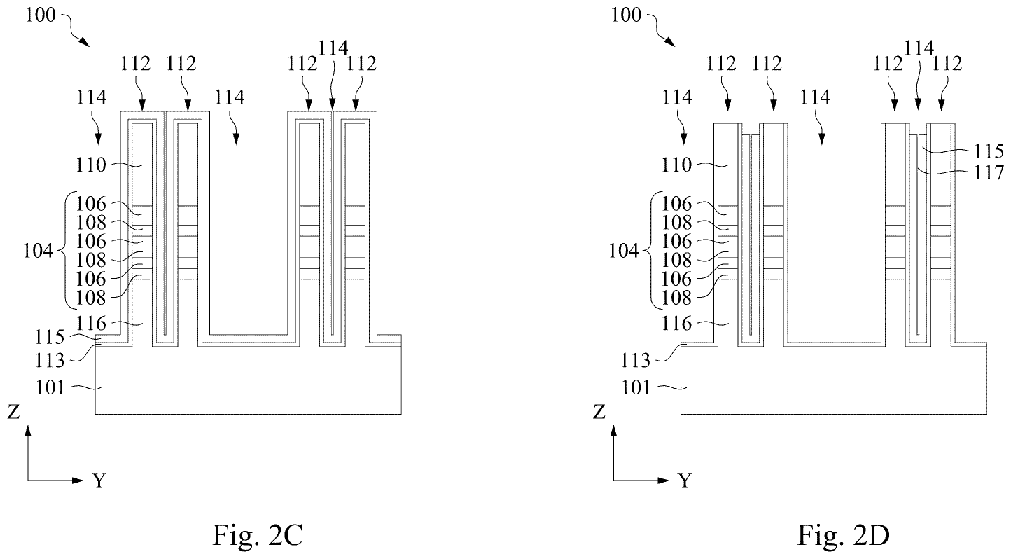

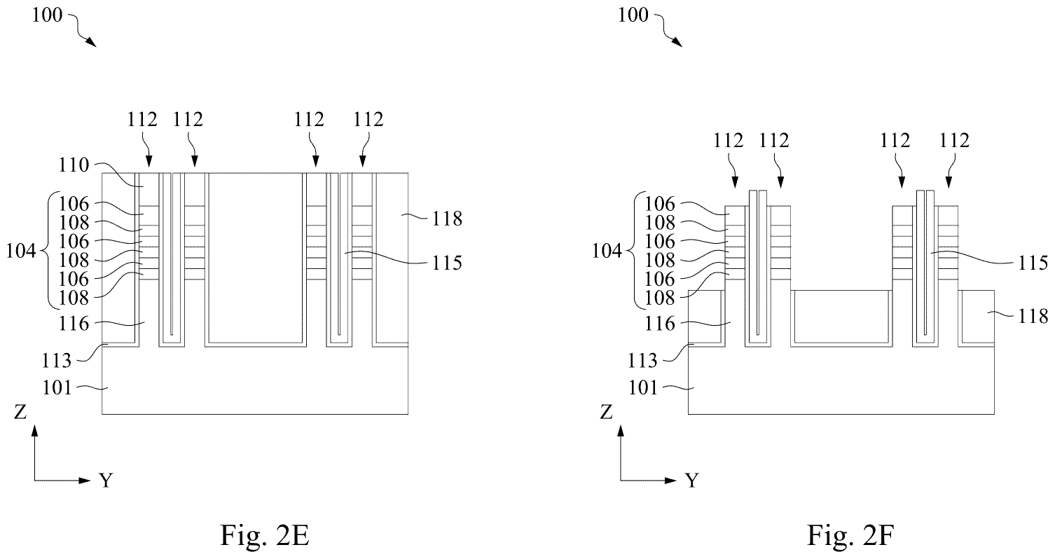

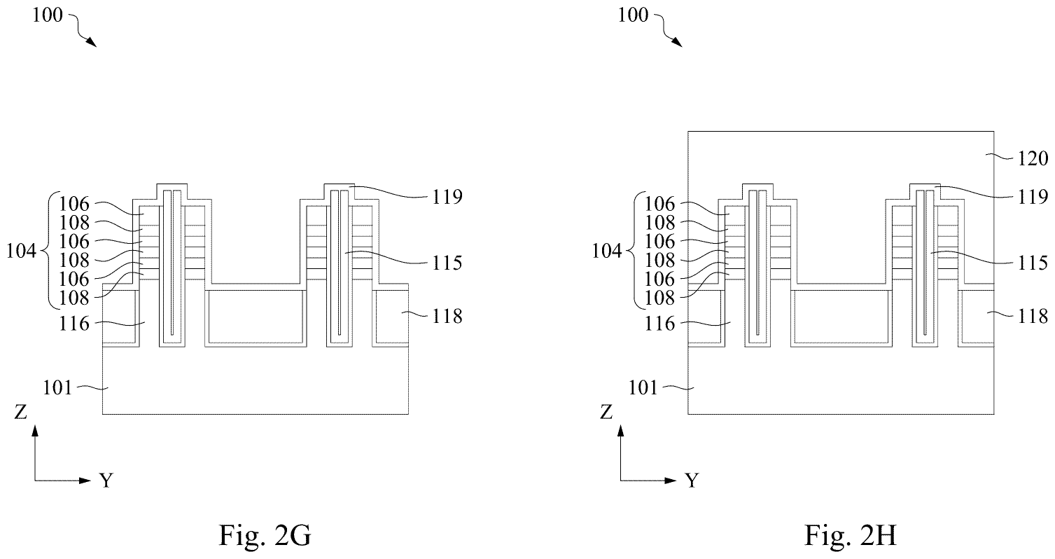

FIGS. 2A-2H are cross-sectional side views of various stages of manufacturing the semiconductor device structure 100 taken along line A-A of FIG. 1, in accordance with some embodiments. As shown in FIG. 2A, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer 110 formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer 110, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer 110, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, the width of the trenches 114 may be different. For example, the trenches 114 include narrow trenches and wide trenches.

In FIG. 2B, one or more liners 113 are formed around the fin structures 112. In some embodiments, the one or more liners 113 includes a single liner. For example, the single liner may be a silicon layer, such as an amorphous silicon layer, or an oxide layer, such as a silicon oxide layer. In some embodiments, the single liner may include a high-k material having a k value greater than that of silicon dioxide. Exemplary materials may include, but are not limited to, metal oxides, such as HfO₂, ZrO₂, TiO₂, Al₂O₃, La₂O₃, Y₂O₃, ScO₂, or alloy metal oxide, such as HfAlOₓ, HfSiOₓ, HfZrOₓ, ZrAlOₓ, ZrSiOₓ, where x may be integers or non-integers. In some embodiments, the thickness of the single liner may range from about 5 angstroms to about 30 angstroms. In some embodiments, the one or more liners 113 includes two liners. For example, the one or more liners 113 includes a first liner deposited around the fin structures 112 and a second liner deposited on the first liner. The first liner may be a silicon layer, and the second liner may be a silicon oxide layer or a high-k dielectric layer. The thickness of the first liner may range from about 5 angstroms to about 10 angstroms, and the thickness of the second liner may range from about 15 angstroms to about 25 angstroms. The one or more liners 113 are formed by one or more conformal processes, such as atomic layer deposition (ALD) process.

In FIG. 2C, a dielectric layer 115 is deposited on the one or more liners 113 in the trenches 114d. The dielectric layer 115 fills the narrow trenches 114 due to the small width of the narrow trenches 114. The dielectric layer 115 does not fill the wide trenches 114 due to the large width of the wide trenches 114, as shown in FIG. 2C. The dielectric layer 115 may include a low-k dielectric material (e.g., a material having a k value lower than that of silicon dioxide), such as SiCN or porous SiO₂. In some embodiments, the dielectric layer 115 is a silicon-containing dielectric material having a k vale less than 7, such as SiO₂, SiCN, SiOC, or SiOCN. The dielectric layer 115 may be formed by a conformal process, such as an ALD process. The dielectric layer 115 may have a thickness ranging from about 5 nm to about 30 nm. If the thickness of the dielectric layer 115 is less than about 5 nm, the narrow trenches 114 may not be filled. On the other hand, if the thickness of the dielectric layer 115 is greater than about 30 nm, the manufacturing cost is increased without significant advantage. In some embodiments, a seam 117 may be formed in the dielectric layer 115.

In FIG. 2D, an etch back process is performed to remove portions of the dielectric layer 115. In some embodiments, portions of the dielectric layer 115 formed in the wide trenches 114 and over the fin structures 112 are removed. The portions of the dielectric layer 115 may be removed by a selective etch process. In some embodiments, because the wide trenches 114 are not completely filled and have a larger width in the Y direction compared to that of the narrow trenches 114 (FIG. 2B), the etchant of the selective etch process removes more of the dielectric layer 115 in the wide trenches 114 than the dielectric layer 115 in the narrow trenches 114b. The portions of the dielectric layer 115 in the wide trenches 114 are etched at a faster rate than the etch rate of the portions of the dielectric layer 115 in the narrow trenches 114. As a result, the portions of the dielectric layer 115 in the wide trenches 114 are removed, while the portions of the dielectric layer 115 in the narrow trenches 114 are recessed, as shown in FIG. 2D. The selective etch process removes the portions of the dielectric layer 115 but does not substantially affect the one or more liners 113.

In FIG. 2E, an insulating material 118 is formed on the substrate 101. The insulating material 118 fills the trenches 114 until the fin structures 112 are embedded in the insulating material 118. Then, a planarization process, such as a chemical mechanical polishing (CMP) process and/or an etch-back process, is performed such that the top of the dielectric layer 115 is exposed. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In FIG. 2F, the insulating material 118 is recessed to form an isolation region. The recessing of the insulating material 118 exposes portions of the fin structures 112, such as the stack of semiconductor layers 104. During the recessing of the insulating material 118, the portions of the one or more liners 113 disposed in the wide trenches 114 may be also recessed, as shown in FIG. 2F. Thereafter, the hard mask layer 110 is removed by any suitable process, such as an etch process. In some embodiments, the hard mask layer 110 is removed during the recessing of the insulating material 118. In some embodiments, the portions of the one or more liners 113 located adjacent the dielectric layer 115 are slightly recessed by the recessing process due to the small critical dimension of the one or more liners 113.

In FIG. 2G, a sacrificial gate dielectric layer 119 is deposited on the fin structures 112 and the insulating material 118. The sacrificial gate dielectric layer 119 may include any suitable dielectric material. In some embodiments, the sacrificial gate dielectric layer 119 includes an oxide, such as silicon oxide. The sacrificial gate dielectric layer 119 may be formed by any suitable process. In some embodiments, the sacrificial gate dielectric layer 119 is a conformal layer and is formed by ALD. The sacrificial gate dielectric layer 119 may include a single layer or a multi-layer structure.

In FIG. 2H, a sacrificial gate electrode layer 120 is deposited on the sacrificial gate dielectric layer 119. The sacrificial gate electrode layer 120 may include silicon, such as polycrystalline silicon or amorphous silicon.

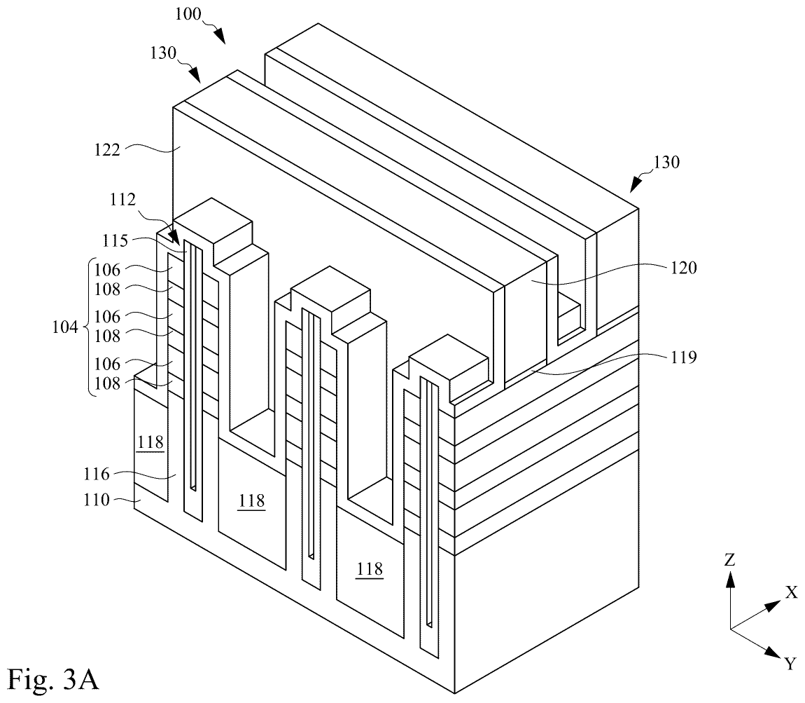

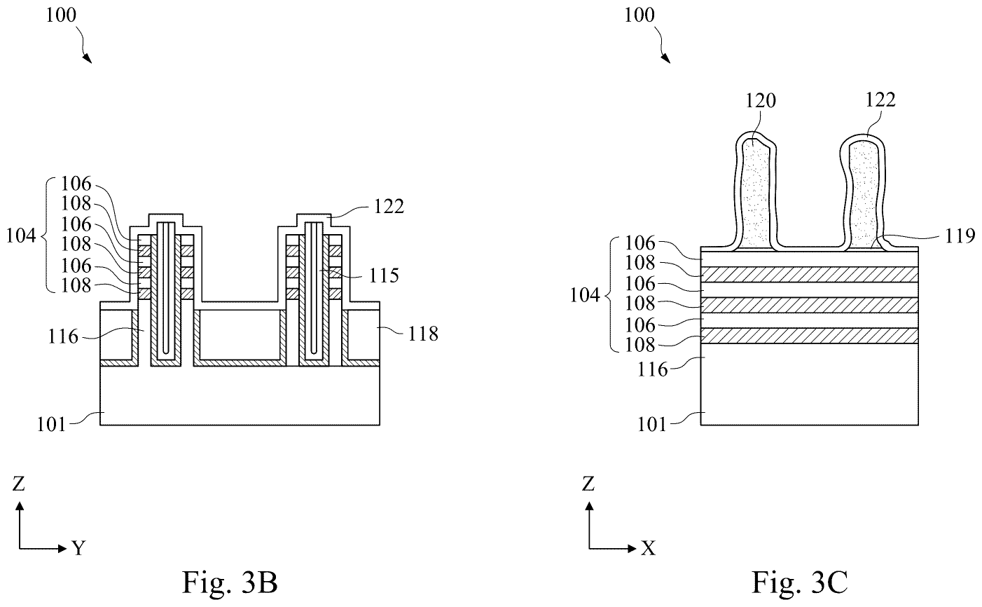

FIGS. 3A-3C are various views of one of various stages of manufacturing the semiconductor device structure 100, in accordance with some embodiments. FIG. 3A is a perspective view of the semiconductor device structure 100, FIG. 3B is a cross-sectional view of the semiconductor device structure 100 at a location outside of the sacrificial gate electrode layer 120 shown in FIG. 3A, and FIG. 3C is a cross-sectional view of the semiconductor device structure 100 at a location across the fin structure 112 shown in FIG. 3A. As shown in FIGS. 3A-3C, the sacrificial gate dielectric layer 119 and the sacrificial gate electrode layer 120 are patterned to form one or more sacrificial gate structures 130. In some embodiments, a mask layer (not shown) may be formed on the sacrificial gate electrode layer 120 for patterning the sacrificial gate electrode layer 120 and the sacrificial gate dielectric layer 119, and the mask layer is part of the sacrificial gate structure 130. The mask layer may include more than one layer, such as an oxide layer and a nitride layer. In some embodiments, as shown in FIG. 3C, the sacrificial gate electrode layer 120 may include a footing profile in the sidewalls. As a result, the sacrificial gate dielectric layer 119 may have a width along the X direction substantially greater than a width of the sacrificial gate electrode layer 120. The footing profile may be also formed in the sidewalls of the sacrificial gate electrode layer 120 located on sidewalls of the stack of semiconductor layers 104.

In FIGS. 3A-3C, a spacer 122 are deposited on the sacrificial gate structures 130, the exposed portions of the fin structures 112, and the insulating material 118. The spacer 122 may include one or more conformal layers. The spacer 122 may be made of a dielectric material such as silicon oxide, silicon nitride, silicon carbide, silicon oxynitride, SiCN, silicon oxycarbide, SiOCN, and/or combinations thereof. In some embodiments, because the width of the sacrificial gate dielectric layer 119 is greater than the width of the sacrificial gate electrode layer 120, portions of the sacrificial gate dielectric layer 119 are disposed under the spacer 122, as shown in FIG. 3C.

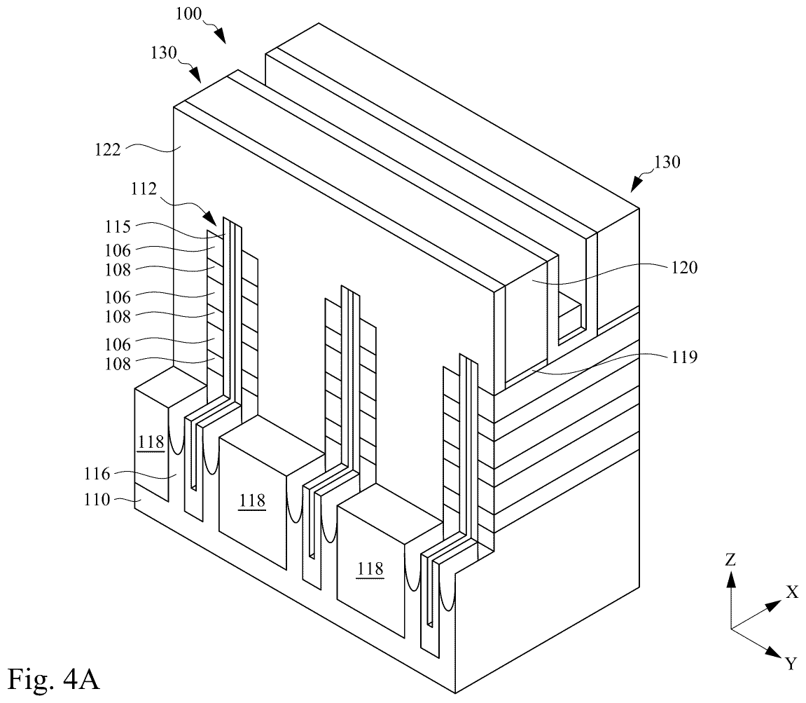

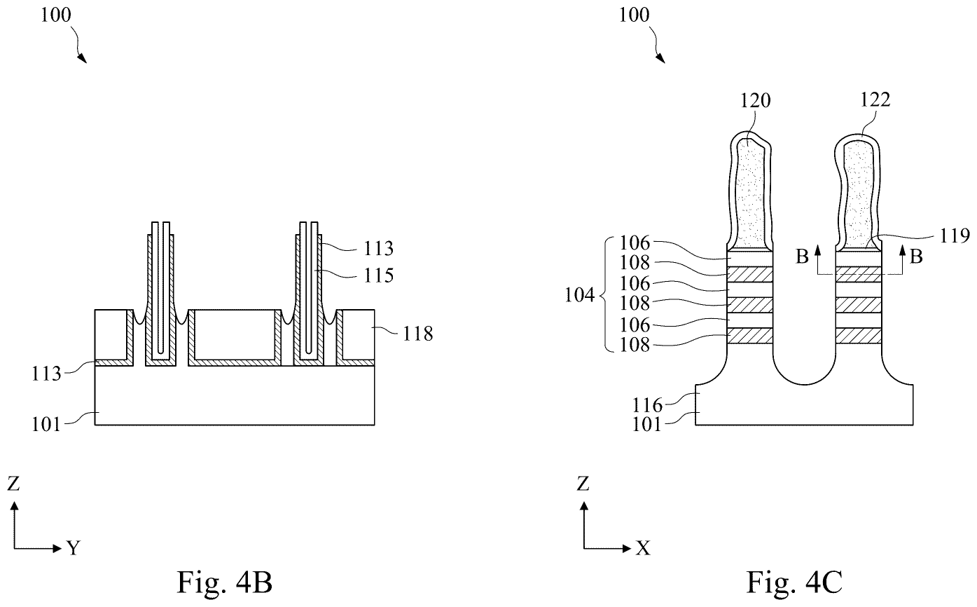

FIGS. 4A-4C are various views of one of various stages of manufacturing the semiconductor device structure 100, in accordance with some embodiments. FIG. 4A is a perspective view of the semiconductor device structure 100, FIG. 4B is a cross-sectional view of the semiconductor device structure 100 at a location outside of the sacrificial gate electrode layer 120 shown in FIG. 4A, and FIG. 4C is a cross-sectional view of the semiconductor device structure 100 at a location across the fin structure 112 shown in FIG. 4A. As shown in FIGS. 4A-4C, an anisotropic etch process is performed to remove portions of the spacers 122 formed on horizontal surfaces, and the exposed portions of the fin structures 112 not covered by the sacrificial gate structures 130 are recessed. The portions of the fin structures 112 that are covered by the sacrificial gate electrode layer 120 of the sacrificial gate structure 130 serve as channel regions for the semiconductor device structure 100.

The portions of the fin structures 112 not covered by the sacrificial gate structure and the spacers 122 are recessed to a level above, at, or below the top surfaces of the isolation material 118. The recess of the portions of the fin structures 112 can be done by an etch process, either isotropic or anisotropic etch process, and the etch process may be selective with respect to the semiconductor materials of the stack of semiconductor layers 104. The dielectric materials of the one or more liners 113, the dielectric layer 115, and the isolating material 118 are not substantially affected by the etch process. The etch process may be a dry etch, such as a RIE, NBE, or the like, or a wet etch, such as using tetramethyalammonium hydroxide (TMAH), ammonium hydroxide (NH₄OH), or any suitable etchant. After recessing the exposed portion of each fin structure 112, a portion of each substrate portion 116 is exposed.

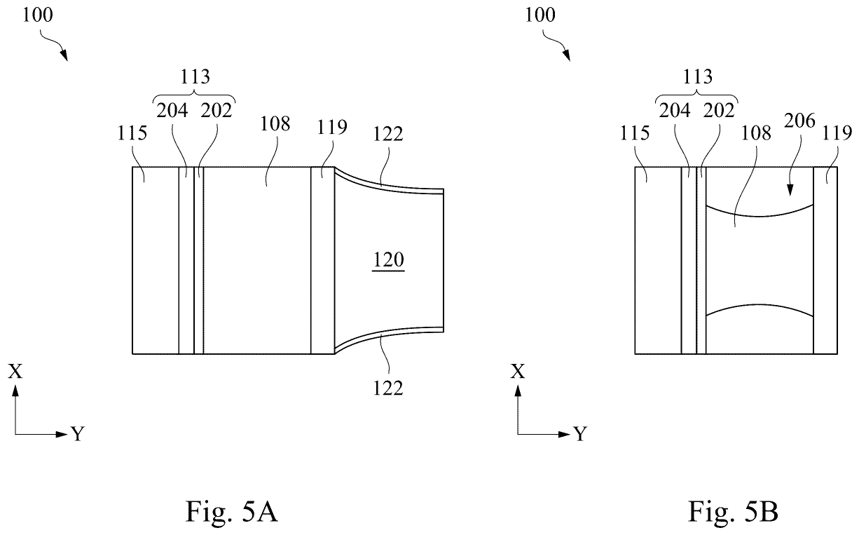

FIGS. 5A and 5B are cross-sectional side views of various stages of manufacturing the semiconductor device structure 100 taken along line B-B of FIG. 4C, in accordance with some embodiments. As shown in FIG. 5A, in some embodiments, the one or more liners 113 includes a first liner 202 and a second liner 204. As described above, the first liner 202 may be a silicon layer, and the second liner 204 may be a silicon oxide layer or a high-k dielectric layer. In some embodiments, under the sacrificial gate structure 130 (FIG. 4A), the second semiconductor layer 108 is located between the sacrificial gate dielectric layer 119 and the first liner 202 of the one or more liners 113, and the second liner 204 is located between the first liner 202 and the dielectric layer 115. In other words, the second liner 204 is in contact with the dielectric layer 115, the first liner 202 is in contact with the second liner 204, the second semiconductor layer 108 is in contact with the first liner 202, and the sacrificial gate dielectric layer 119 is in contact with the second semiconductor layer 108 along the Y direction, as shown in FIG. 5A. A portion of the sacrificial gate electrode layer 120 including the footing profile and a portion of the spacer 122 are in contact with the sacrificial gate dielectric layer 119. The portion of the sacrificial gate electrode layer 120 and the portion of the spacer 122 are omitted in FIGS. 5B, 6, 7A, 7B, 11A, 11B for clarity.

Next, as shown in FIG. 5B, edge portions of each second semiconductor layer 108 of the stack of semiconductor layers 104 are removed horizontally along the X direction. The removal of the edge portions of the second semiconductor layers 108 forms cavities 206, as shown in FIG. 5B. In some embodiments, the edge portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

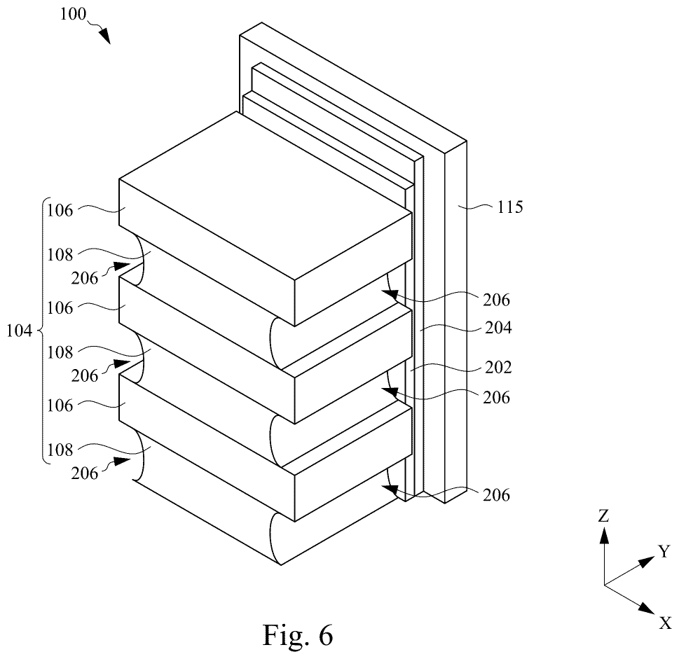

FIG. 6 is a perspective view of a portion of the semiconductor device structure 100 of FIG. 5B, in accordance with some embodiments. As shown in FIG. 6, the cavities 206 are formed on opposite edges of the second semiconductor layers 108, and portions of the first liner 202 are exposed in the cavities 206. Portions of the first liner 202 may be also exposed in areas not covered by the sacrificial gate structures 130 (FIG. 4A).

In some embodiments, after the removal of edge portions of the second semiconductor layers 108, inner spacers may be formed to fill the cavities 206. Each inner spacer has a width along the Y direction. With the small width inner spacer located between the first liner 202 and the sacrificial gate dielectric layer 119, the process window for subsequent replacement gate process may be narrowed. Furthermore, the risk of electric short between the subsequently formed S/D region 146 and subsequently formed gate electrode layer 136 may be increased. Thus, in order to widen the process window for the replacement gate process and to reduce the risk of electric short between the S/D region 146 and the gate electrode layer 136, the width of the inner spacer is increased. The width of the inner spacer may be increased by enlarging the cavities 206 along the Y direction.

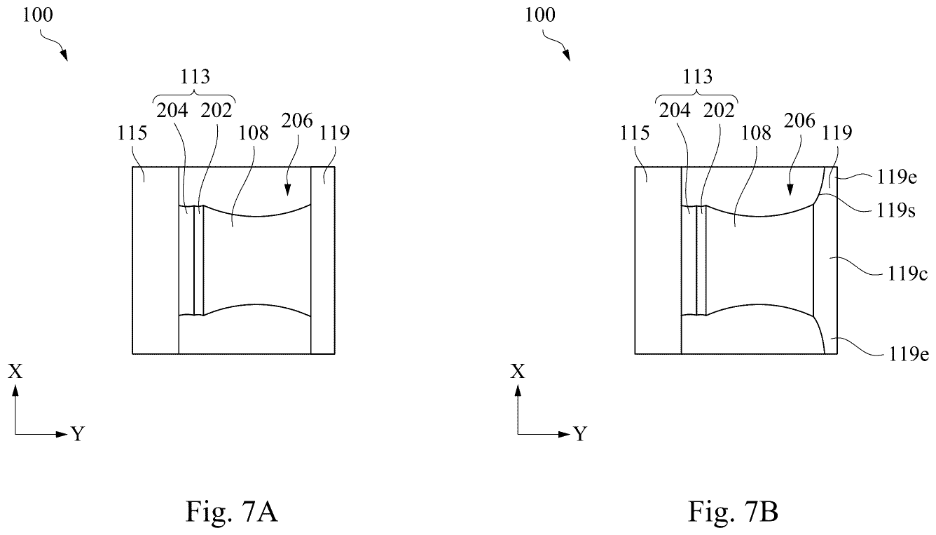

FIGS. 7A and 7B are cross-sectional side views of various stages of manufacturing the semiconductor device structure 100 taken along line B-B of FIG. 4C, in accordance with some embodiments. As shown in FIG. 7A, in some embodiments, portions of the first liner 202 and second liner 204 are removed to enlarge the cavities 206 along the Y direction. In some embodiments, the portions of the first and second liners 202, 204 are removed by one or more etch processes. In some embodiments, a first etch process is performed to remove the exposed portions of the first liner 202. The first etch process may be a selective etch process, such as a selective wet etch process. The first etch process does not substantially affect other components of the semiconductor device structure 100. After the exposed portion of the first liner 202 is removed, a portion of the second liner 204 is exposed. A second etch process is then performed to remove the exposed portion of the second liner 204. The second etch process may be a selective etch process, such as a selective wet etch process. The second etch process does not substantially affect other components of the semiconductor device structure 100. In some embodiments, a single etch process may be performed to remove the portions of the first and second liners 202, 204, while other components of the semiconductor device structure 100 are not substantially affected by the single etch process.

In some embodiments, the cavities 206 may be further enlarged along the Y direction by removing portions of the sacrificial gate dielectric layer 119, as shown in FIG. 7B. In some embodiments, the portions of the sacrificial gate dielectric layer 119 are removed during the removal of the portions of the first and second liners 202, 204. For example, the one or more etch processes to remove the portions of the first and second liners 202, 204 may also remove the portions of the sacrificial gate dielectric layer 119. The etch rate of the first and second liners 202, 204 of the one or more etch processes is substantially greater than the etch rate of the sacrificial gate dielectric layer 119. As a result, the cavity 206 does not extend through the sacrificial gate dielectric layer 119.

In some embodiments, the removal of the portions of the sacrificial gate dielectric layer 119 and the removal of the portions of the first and second liners 202, 204 are performed by distinct processes. For example, the portions of the sacrificial gate dielectric layer 119 are removed before or after the removal of the portions of the first and second liners 202, 204. The portions of the sacrificial gate dielectric layer 119 are removed by an etch process, such as a selective etch process. The selective etch process does not substantially affect other components of the semiconductor device structure 100. In some embodiments, as shown in FIG. 7B, the cavity 206 does not extend through the sacrificial gate dielectric layer 119. After the removal of the portions of the sacrificial gate dielectric layer 119, the remaining sacrificial gate dielectric layer 119 includes edge portions 119e and a center portion 119c located between the edge portions 119e. The edge portions 119e are exposed in the cavities 206, and the center portion 119c is in contact with the second semiconductor layer 108. In some embodiments, each edge portion 119e of the sacrificial gate dielectric layer 119 has a curved surface 119s exposed in the cavity 206. In some embodiments, the sacrificial gate dielectric layer 119 includes a varying width along the Y direction. The width of the edge portion 119e varies and increases in a direction towards the center portion 119c. The width of the center portion 119c is substantially constant, as shown in FIG. 7B.

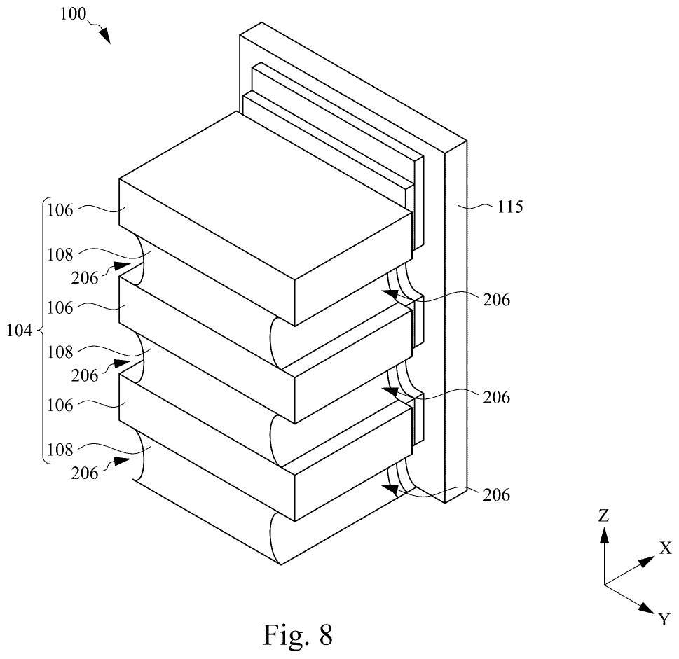

FIG. 8 is a perspective view of a portion of the semiconductor device structure 100 of FIG. 7B, in accordance with some embodiments. As shown in FIG. 8, portions of the first and second liners 202, 204 are removed, and the dielectric layer 115 is exposed in the cavities 206.

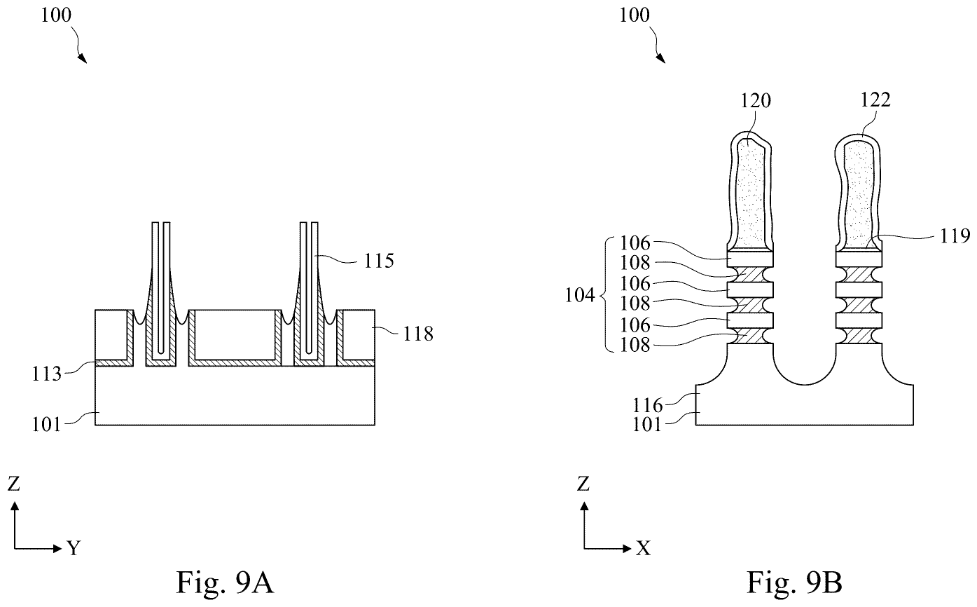

FIGS. 9A and 9B are cross-sectional side views of one of various stages of manufacturing the semiconductor device structure 100, in accordance with some embodiments. FIG. 9A is a cross-sectional view of the semiconductor device structure 100 at a location outside of the sacrificial gate electrode layer 120, and FIG. 9B is a cross-sectional view of the semiconductor device structure 100 at a location across the fin structure. FIGS. 9A and 9B illustrate the semiconductor device structure 100 after the removal of the portions of the first and second liners 202, 204 and the portions of the sacrificial gate dielectric layer 119. As shown in FIG. 9A, the exposed portions of the one or more liner 113 (e.g., the first liner 202 and the second liner 204) are removed.

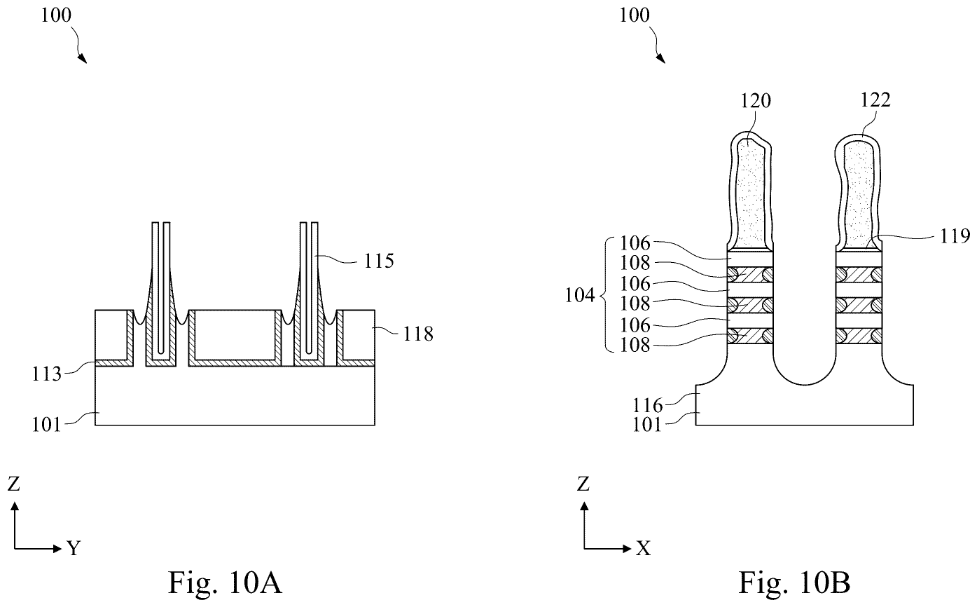

Next, as shown in FIGS. 10A and 10B, inner spacers 126 are formed in the cavities 206. The inner spacers 126 may be formed by first depositing a dielectric layer (not shown) on the exposed surfaces of the semiconductor device structure 100 and followed by an anisotropic etch process to remove portions of the dielectric layer other than the inner spacers 126. The inner spacers 126 are protected by the first semiconductor layers 106 during the removal of the portions of the dielectric layer. The inner spacer 126 may include any suitable dielectric material. In some embodiments, the inner spacer 126 includes SiON, SiCN, SiOC, SiOCN, SiN, SIO2, AlO, or HfO. In some embodiments, the inner spacer 126 includes a low-K dielectric material (with K value less than 7). In some embodiments, the inner spacer 126 includes a high-K dielectric material (with K value greater than or equal to 7).

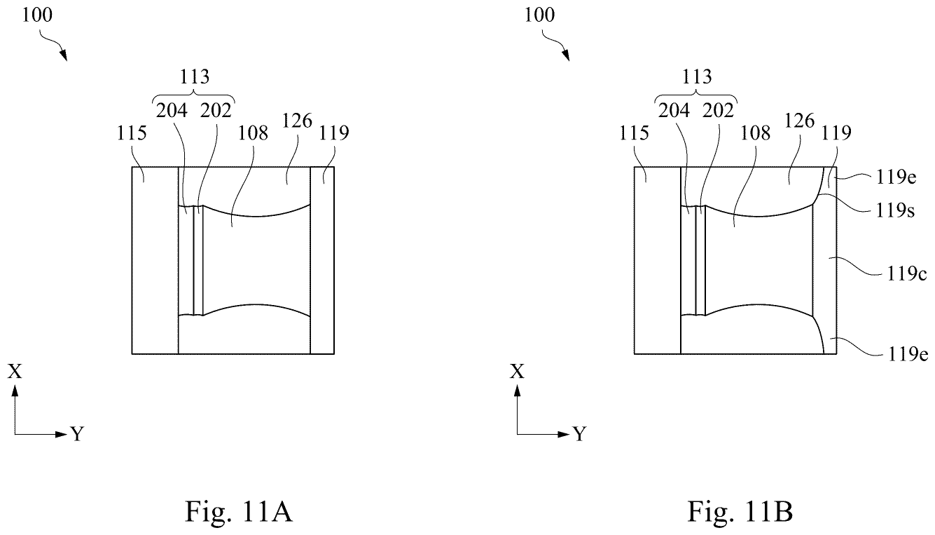

FIGS. 11A and 11B are cross-sectional top views of one of various stages of manufacturing the semiconductor device structure 100 taken along line B-B of FIG. 4C, in accordance with some embodiments. FIGS. 11A and 11B illustrate top views of the inner spacers 126 in accordance with some embodiments. As shown in FIGS. 11A and 11B, the inner spacer 126 is formed between the dielectric layer 115 and the sacrificial gate dielectric layer 119. In some embodiments, the inner spacer 126 is in contact with the dielectric layer 115, the first liner 202, the second liner 204, the second semiconductor layer 108, and the sacrificial gate dielectric layer 119. The inner spacer 126 has an increased width, which can lead to widened process window for the replacement gate process and reduced risk of electric short between the subsequently formed S/D region 146 and the subsequently formed gate electrode layer 136. In some embodiments, portions of the sacrificial gate dielectric layer 119 are not removed, as shown in FIG. 11A. In some embodiments, portions of the sacrificial gate dielectric layer 119 are removed, as shown in FIG. 11B.

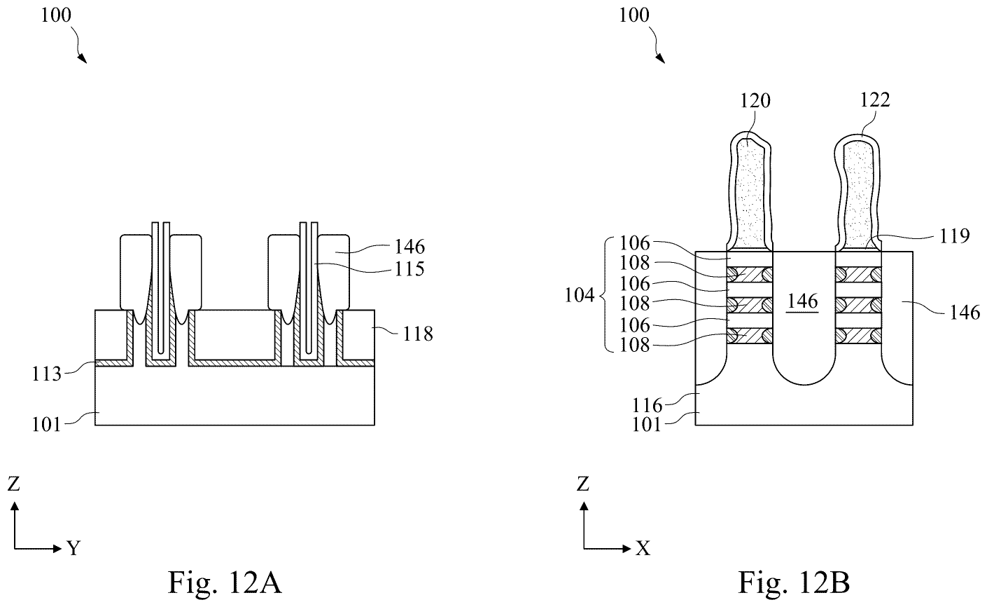

FIGS. 12A and 12B are cross-sectional side views of one of various stages of manufacturing the semiconductor device structure 100, in accordance with some embodiments. As shown in FIGS. 12A and 12B, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, as shown in FIG. 12A, the dielectric layer 115 prevents the merging of adjacent S/D regions 146.

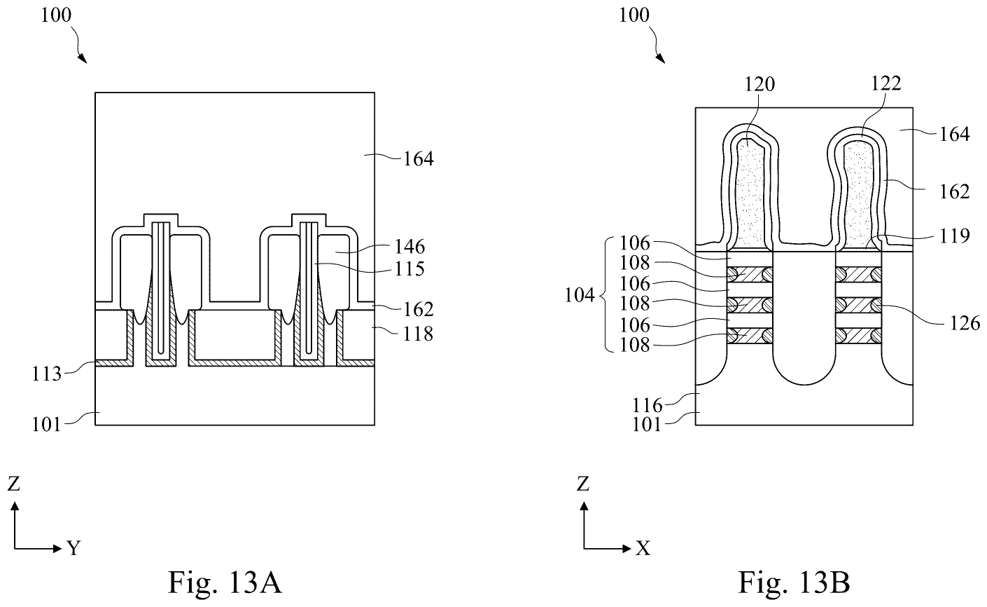

FIGS. 13A and 13B are cross-sectional side views of one of various stages of manufacturing the semiconductor device structure 100, in accordance with some embodiments. As shown in FIGS. 13A and 13B, a contact etch stop layer (CESL) 162 is conformally formed on the exposed surfaces of the semiconductor device structure 100. The CESL 162 covers the spacer 122, the insulating material 118, the S/D regions 146, and the dielectric layer 115. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 120 is exposed.

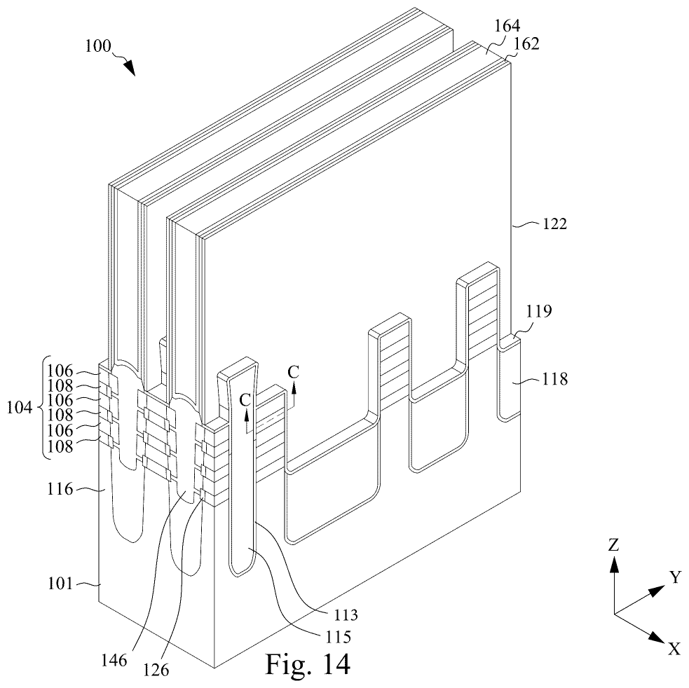

FIG. 14 is a perspective view of one of the various stages of manufacturing the semiconductor device structure 100, in accordance with some embodiments. As shown in FIG. 14, the sacrificial gate electrode layer 120 is removed. The removal of the sacrificial gate electrode layer 120 forms an opening between spacers 122 and between adjacent stacks of semiconductor layers 104. The ILD layer 164 protects the S/D regions 146 during the removal process. The sacrificial gate electrode layer 120 can be removed using plasma dry etching and/or wet etching. In some embodiments, a wet etchant such as a tetramethylammonium hydroxide (TMAH) solution can be used to selectively remove the sacrificial gate electrode layer 120 but not the spacers 122, the sacrificial gate dielectric layer 119, the ILD layer 164, and the CESL 162.

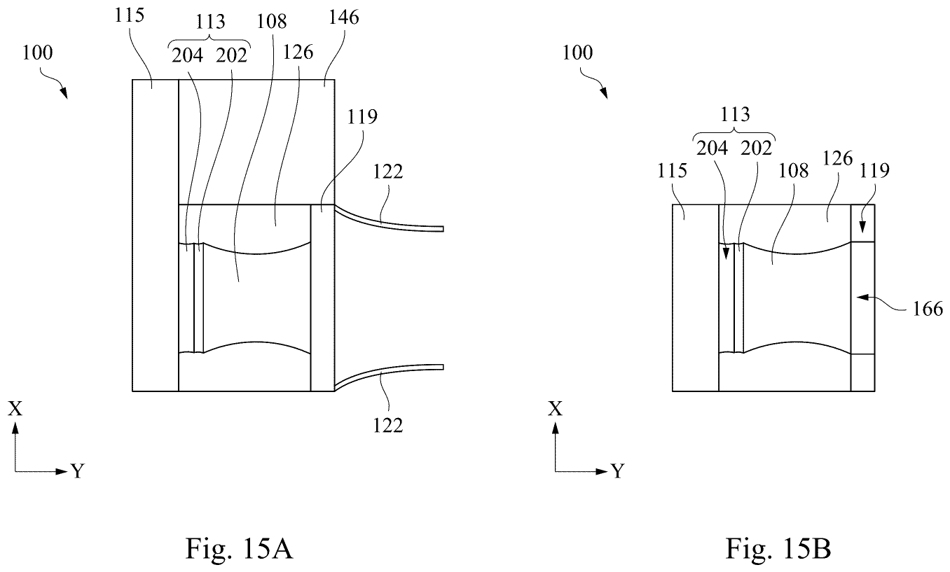

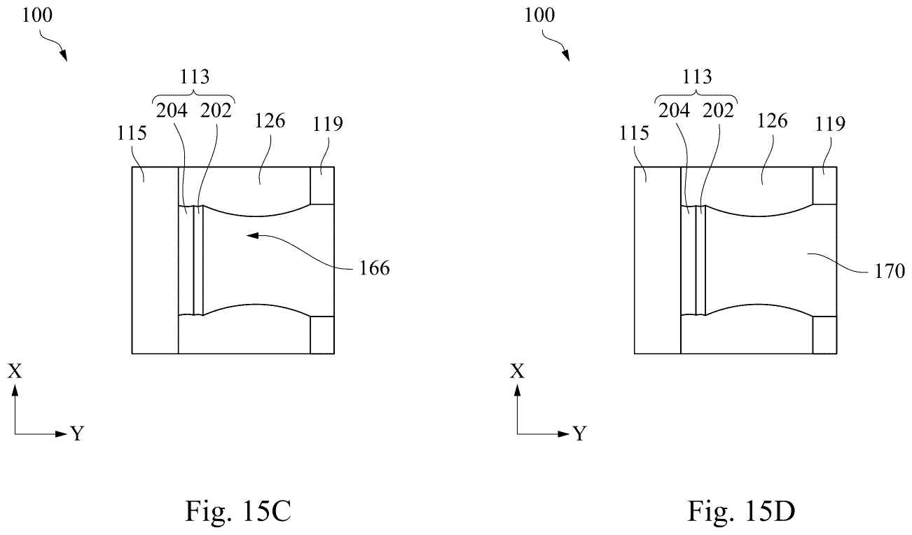

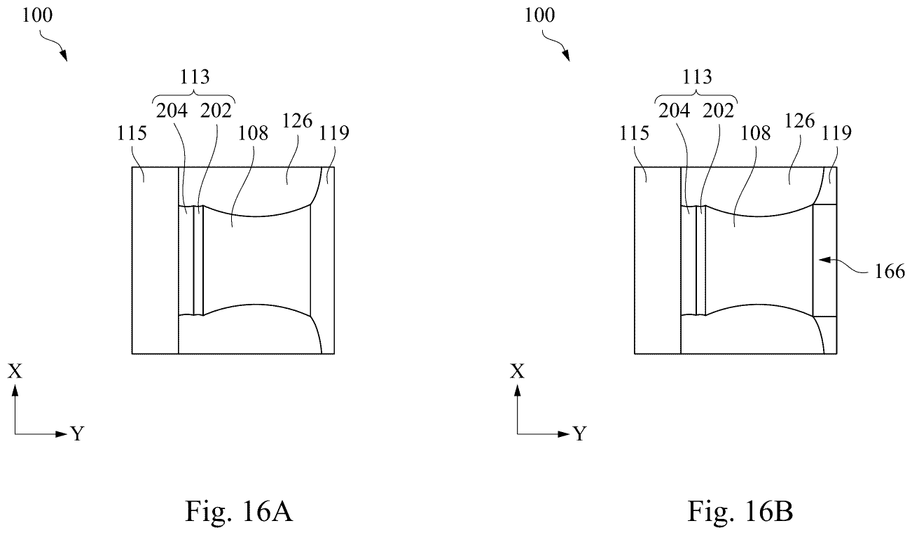

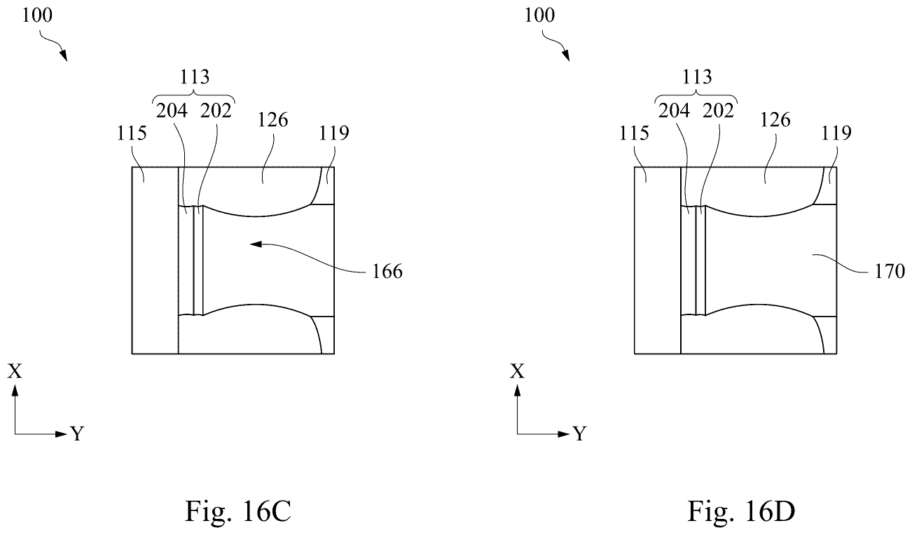

FIGS. 15A-15D are cross-sectional top views of various stages of manufacturing the semiconductor device structure 100 taken along line C-C of FIG. 14, in accordance with some embodiments. As shown in FIG. 15A, the sacrificial gate electrode layer 120 is removed, and the spacer 122 covers portions of the sacrificial gate dielectric layer 119. The S/D region 146 is disposed adjacent the inner spacer 126 and the sacrificial gate dielectric layer 119. The dielectric layer 115 extends to adjacent the S/D region 146, as shown in FIG. 15A. The spacer 122, the S/D region 146, and the portion of the dielectric layer 115 extending to adjacent the S/D region 146 are omitted in FIGS. 15B-15D and 16A-16D for clarity. Next, as shown in FIG. 15B, exposed portion of the sacrificial gate dielectric layer 119 is removed to create an opening 166. The exposed portion of the sacrificial gate dielectric layer 119 may be removed by any suitable process, such as a selective etch process that does not substantially affect other components of the semiconductor device structure 100. Portions of the sacrificial gate dielectric layer 119 covered by the spacer 122 (FIG. 15A) are not removed. The first and second semiconductor layers 106, 108 are exposed in the openings 166. Next, as shown in FIG. 15C, the second semiconductor layers 108 are removed. The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 122, the dielectric layer 115, and the ILD layer 164. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate structure 170 is formed to surround the exposed portions of the first semiconductor layers 106, as shown in FIG. 15D. In some embodiments, the gate structure 170 includes a gate dielectric layer and gate electrode layer formed on the gate dielectric layer. In some embodiments, an interfacial layer (IL) (not shown) is formed between the gate dielectric layer and the exposed surfaces of the first semiconductor layers 106. In some embodiments, the gate dielectric layer includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer may be formed by CVD, ALD or any suitable deposition technique. The gate electrode layer may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or any combinations thereof. The gate electrode layer may be formed by CVD, ALD, electro-plating, or other suitable deposition technique. The gate electrode layer may be also deposited over the upper surface of the ILD layer 164. The gate dielectric layer and the gate electrode layer formed over the ILD layer 164 are then removed by using, for example, CMP, until the top surface of the ILD layer 164 is exposed.

As shown in FIG. 15D, in some embodiments, the one or more liners 113 have a combined width along the Y direction ranging from about 3 Angstroms to about 200 Angstroms. The one or more liners 113 may include a number of liners, and the number may be less than or equal to 10. In some embodiments, the sacrificial gate dielectric layer 119 has a substantially constant width along the Y direction ranging from about 3 Angstroms to about 200 Angstroms. The sacrificial gate dielectric layer 119 may include one or more layers, such as less than or equal to 10 layers. In some embodiments, the one or more liners 113 includes two liners, and the sacrificial gate dielectric layer 119 includes a single layer. The sacrificial gate dielectric layer 119 protects the first semiconductor layers 106 during the removal of the sacrificial gate electrode layer 120. In some embodiments, as shown in FIG. 15D, the inner spacer 126 is disposed between the dielectric layer 115 and the sacrificial gate dielectric layer 119. The inner spacer 126 may be in contact with a side surface of the one or more liners 113. For example, the inner spacer 126 is in contact with a side surface of the first liner 202 and a side surface of the second liner 204. The side surfaces of the first and second liners 202, 204 may be substantially perpendicular to major surfaces of the first and second liners 202, 204. In some embodiments, the gate structure 170 is in contact with the one or more liners 113, the inner spacer 126 and the sacrificial gate dielectric layer 119. In some embodiments, the gate structure 170 includes the gate dielectric layer, which is in contact with the one or more liners 113, the inner spacer 126 and the sacrificial gate dielectric layer 119.

FIGS. 16A-16D are cross-sectional top views of various stages of manufacturing the semiconductor device structure 100 taken along line C-C of FIG. 14, in accordance with alternative embodiments. FIGS. 16A-16D illustrate embodiments with the recessed sacrificial gate dielectric layer 119. As shown in FIG. 16A, after the removal of the sacrificial gate electrode layer 120, the spacer 122 (FIG. 15A) covers portions of the sacrificial gate dielectric layer 119. Next, as shown in FIG. 16B, the exposed portion of the sacrificial gate dielectric layer 119 is removed to form the opening 166. Next, as shown in FIG. 16C, the second semiconductor layers 108 are removed. Then, the gate structure 170 is deposited in the opening 166, as shown in FIG. 16D. In some embodiments, as described above, the width of the sacrificial gate dielectric layer 119 is not constant, as shown in FIG. 16D. The width of the sacrificial gate dielectric layer 119 may range from about 3 Angstroms to about 200 Angstroms.

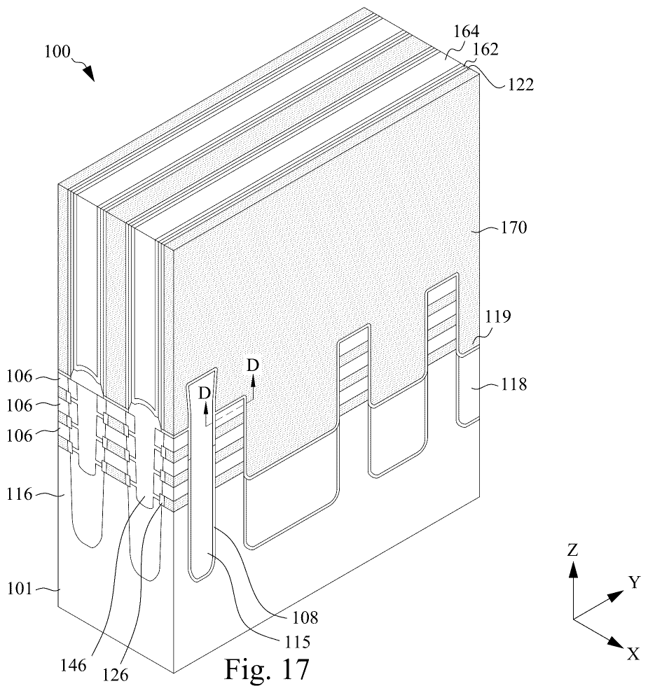

FIG. 17 is a perspective view of one of the various stages of manufacturing the semiconductor device structure 100, in accordance with some embodiments. As shown in FIG. 17, the gate structure 170 surrounds the first semiconductor layers 106 and a top portion of the dielectric layer 115. In some embodiments, the IL (not shown) is selectively formed on the first semiconductor layers 106, the gate dielectric layer is a conformal layer, and the gate electrode layer is formed on the gate dielectric layer.

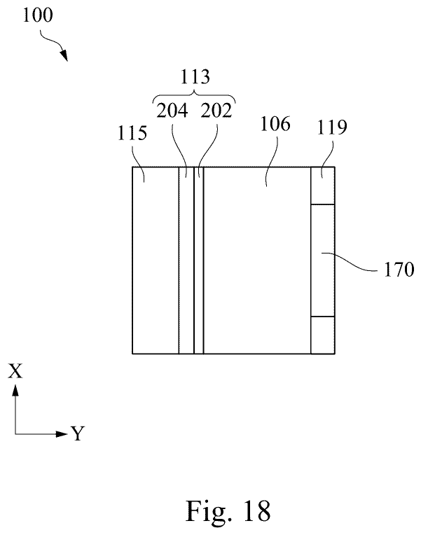

FIG. 18 is a cross-sectional top view of one of various stages of manufacturing the semiconductor device structure 100 taken along line D-D of FIG. 17, in accordance with some embodiments. FIG. 18 illustrates a top view of the first semiconductor layer 106 and the adjacent layers. As shown in FIG. 18, the first semiconductor layer 106 is disposed between the one or more liners 113 and the sacrificial gate dielectric layer 119. The sacrificial gate dielectric layer 119 is covered by the spacer 122 (FIG. 15A) and is not removed during the replacement gate process. As shown in FIG. 18, the one or more liners 113 are not recessed, compared to the one or more liners 113 shown in FIGS. 15A and 16A. Because of the enlarged cavities 206 (FIG. 5B) created by the removal of the edge portions of the second semiconductor layers 108, the portions of the one or more liners 113 are removed, as shown in FIG. 7A. However, the edge portions of the first semiconductor layers 106 are not removed. Thus, the portions of the one or more liners 113 located adjacent the first semiconductor layers 106 are not affected by the process that removes the portions of the one or more liners 113 located adjacent the second semiconductor layers 108. In some embodiments, each first semiconductor layer 106 has a width along the Y direction, and the width of the first semiconductor layer 106 is substantially less than the width of the inner spacer 126 (FIG. 16A) due to the recessed one or more liners 113. In some embodiments, a length of the first semiconductor layer 106 along the X direction is substantially greater than a length of the inner spacer 126 along the X direction, as shown in FIG. 13B. The thickness of the inner spacer 126 along the Z direction may be greater than, equal to, or less than the thickness of the first semiconductor layer 106 along the Z direction. In some embodiments, the thickness of the inner spacer 126 is substantially greater than the thickness of the first semiconductor layer 106. The portion of the sacrificial gate dielectric layer 119 located adjacent the first semiconductor layer 106 is also not removed. In some embodiments, the difference between the width of the portion of the sacrificial gate dielectric layer 119 located adjacent the first semiconductor layer 106 and the width of the portion of the sacrificial gate dielectric layer 119 located adjacent the gate structure 170 (FIG. 16D) may be greater than 3 Angstroms. In some embodiments, the portion of the one or more liners 113 disposed adjacent the first semiconductor layer 106 has a first length along the X direction (FIG. 18) and the portion of the one or more liners 113 disposed adjacent the gate structure 170 has a second length along the X direction (FIG. 16D). In some embodiments, the first length is substantially greater than the second length, as a result of the recessed portion of the one or more liners 113 located adjacent the gate structure 170 to form the enlarged inner spacer 126.

Embodiments of the present disclosure provide a semiconductor device structure including an enlarged inner spacer 126. The inner spacer 126 may be disposed between a dielectric layer 115 and a sacrificial gate dielectric layer 119. The inner spacer 126 may be in contact with a side surface of one or more liners 113. Some embodiments may achieve advantages. For example, the enlarged inner spacers 126 can lead to better process window for defect reduction during the replacement gate process.

An embodiment is a semiconductor device structure. The structure includes a semiconductor layer disposed over a substrate, and the semiconductor layer has a first length and a first width. The structure further includes a first inner spacer disposed on the semiconductor layer, and the first inner spacer has a second length substantially less than the first length and a second width substantially greater than the first width. The structure further includes a gate structure disposed adjacent the first inner spacer, and the gate structure surrounds at least a portion of the semiconductor layer.

Another embodiment is a semiconductor device structure. The structure includes a first semiconductor layer disposed over a substrate, one or more liners disposed adjacent the first semiconductor layer, a dielectric layer disposed adjacent the one or more liners, a gate structure surrounding at least a portion of the first semiconductor layer, a sacrificial gate dielectric layer in contact with the gate structure, and a first inner spacer disposed on the first semiconductor layer. The first inner spacer is disposed between the dielectric layer and the sacrificial gate dielectric layer, and the first inner spacer is in contact with one or more side surfaces of the one or more liners.

A further embodiment is a method for forming a semiconductor device structure. The method includes forming a fin structure, and the fin structure comprises a first semiconductor layer and a second semiconductor layer. The method further includes forming one or more liners around the fin structure, forming a dielectric layer on the one or more liners, forming a sacrificial gate structure over a portion of the fin structure, recessing exposed portions of the fin structure, removing edge portions of the second semiconductor layer to create cavities and to expose portions of the one or more liners, enlarging the cavities by removing the exposed portions of the one or more liners, and forming inner spacers in the cavities.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a semiconductor layer disposed over a substrate, wherein the semiconductor layer has a first length and a first width;
a first inner spacer disposed on the semiconductor layer, wherein the first inner spacer has a second length substantially less than the first length and a second width substantially greater than the first width; and
a gate structure disposed adjacent the first inner spacer, wherein the gate structure surrounds at least a portion of the semiconductor layer.

2. The semiconductor device structure of claim 1, further comprising a second inner spacer disposed on the semiconductor layer, wherein the gate structure is disposed between the first and second inner spacers.

3. The semiconductor device structure of claim 2, further comprising one or more liners disposed between the first and second inner spacers.

4. The semiconductor device structure of claim 1, further comprising a dielectric layer and a sacrificial gate dielectric layer, wherein the first inner spacer is disposed between the dielectric layer and the sacrificial gate dielectric layer.

5. The semiconductor device structure of claim 4, wherein the sacrificial gate dielectric layer has a constant width.

6. The semiconductor device structure of claim 4, wherein the sacrificial gate dielectric layer has a varying width.

7. A semiconductor device structure, comprising:
a first semiconductor layer disposed over a substrate;
one or more liners disposed adjacent the first semiconductor layer;
a dielectric layer disposed adjacent the one or more liners;
a gate structure surrounding at least a portion of the first semiconductor layer;
a sacrificial gate dielectric layer in contact with the gate structure; and
a first inner spacer disposed on the first semiconductor layer, wherein the first inner spacer is disposed between the dielectric layer and the sacrificial gate dielectric layer, and the first inner spacer is in contact with one or more side surfaces of the one or more liners.

8. The semiconductor device structure of claim 7, wherein the one or more liners comprises a first liner in contact with the gate structure and a second liner disposed between the first liner and the dielectric layer.

9. The semiconductor device structure of claim 8, further comprising a second inner spacer disposed on the first semiconductor layer, wherein the one or more liners and the gate structure are disposed between the first and second inner spacers.

10. The semiconductor device structure of claim 9, wherein the second inner spacer is in contact with the dielectric layer.

11. The semiconductor device structure of claim 7, wherein the sacrificial gate dielectric layer is a multi-layer structure.

12. The semiconductor device structure of claim 7, further comprising a first source/drain region and a second source/drain region, wherein the dielectric layer is disposed between the first and second source/drain regions.

13. The semiconductor device structure of claim 12, wherein the one or more liners comprises a first portion disposed adjacent the first semiconductor layer and a second portion disposed adjacent the gate structure.

14. The semiconductor device structure of claim 13, wherein the first portion of the one or more liners has a first length, and the second portion of the one or more liners has a second length substantially less than the first length.

15. The semiconductor device structure of claim 7, wherein the sacrificial gate dielectric layer has a constant width.

16. The semiconductor device structure of claim 7, wherein the sacrificial gate dielectric layer has a varying width.

17. A method for forming a semiconductor device structure, comprising:
forming a fin structure, wherein the fin structure comprises a first semiconductor layer and a second semiconductor layer;
forming one or more liners around the fin structure;
forming a dielectric layer on the one or more liners;
forming a sacrificial gate structure over a portion of the fin structure;
recessing exposed portions of the fin structure;
removing edge portions of the second semiconductor layer to create cavities and to expose portions of the one or more liners;
enlarging the cavities by removing the exposed portions of the one or more liners; and
forming inner spacers in the cavities.

18. The method of claim 17, wherein the sacrificial gate structure comprises a sacrificial gate dielectric layer and a sacrificial gate electrode layer.

19. The method of claim 18, further comprising removing portions of the sacrificial gate dielectric layer to further enlarging the cavities.

20. The method of claim 18, wherein the removing of the exposed portions of the one or more liners and the removing of the portions of the sacrificial gate dielectric layer are performed by distinct processes.
